(19) United States
(12) Patent Application Publication
(10) Pub. No.: US 2026/0005019 A1
(43) Pub. Date: Jan. 1, 2026

(54) METHOD OF MANUFACTURING SEMICONDUCTOR DEVICE AND SUBSTRATE TREATMENT APPARATUS

(71) Applicant: Kioxia Corporation, Tokyo (JP)

(72) Inventors: Chihiro UMEDA, Yokkaichi (JP); Yuta SAITO, Yokkaichi (JP); Hiroyuki YAMASHITA, Yokkaichi (JP)

(73) Assignee: Kioxia Corporation, Tokyo (JP)

(21) Appl. No.: 19/076,537

(22) Filed: Mar. 11, 2025

(30) Foreign Application Priority Data
Jun. 28, 2024 (JP) 2024-105391

(51) Int. Cl. H01L 21/02; H01J 37/32

(52) U.S. Cl. CPC H01L 21/0234; H01J 37/3244; H01L 21/0217; H01J 2237/338

(57) ABSTRACT

According to one embodiment, there is provided a method of manufacturing a semiconductor device. The method comprises radically oxidizing a first film by using a plasma generated by a treatment gas including a hydrogen isotope gas.

### CROSS-REFERENCE TO RELATED APPLICATIONS

This application is based upon and claims the benefit of Japanese Patent Application No. 2024-105391, filed on Jun. 28, 2024; the entire contents of which are incorporated herein by reference.

### FIELD

Embodiments described herein relate generally to a method of manufacturing a semiconductor device and a substrate treatment apparatus.

### BACKGROUND

In a manufacturing process of a semiconductor device, a predetermined film may be deposited on or above a substrate, and the deposited predetermined film may be radically oxidized. In the manufacturing process of the semiconductor device, it is desired that radical oxidation is efficiently performed.

### BRIEF DESCRIPTION OF THE DRAWINGS

FIG. 1 is a flowchart illustrating a method of manufacturing a semiconductor device according to an embodiment;

FIGS. 2A to 2E are cross-sectional diagrams illustrating the method of manufacturing the semiconductor device according to the embodiment;

FIG. 3 is a diagram illustrating a configuration of a substrate treatment apparatus used in the method of manufacturing the semiconductor device according to the embodiment;

FIG. 4 is a diagram illustrating a change in an oxide film thickness according to a treatment time (in a case of a flow rate ratio of 30%);

FIG. 5 is a diagram illustrating a change in an oxide film thickness according to a treatment time (in a case of a flow rate ratio of 20%);

FIG. 6 is a diagram illustrating a change in an oxide film thickness according to a treatment time (in a case of a flow rate ratio of 5%);

FIG. 7 is a diagram illustrating a change in hydroxy radical OH⁺ emission intensity according to a flow rate ratio of hydrogen or an isotope thereof;

FIG. 8 is a flowchart illustrating a method of manufacturing a semiconductor device according to a first modification of the embodiment;

FIG. 9 is a diagram illustrating a configuration of a substrate treatment apparatus used in the method of manufacturing the semiconductor device according to the first modification of the embodiment;

FIG. 10 is a flowchart illustrating a method of manufacturing a semiconductor device according to a second modification of the embodiment;

FIGS. 11A and 11B are cross-sectional diagrams illustrating the method of manufacturing the semiconductor device according to the second modification of the embodiment;

FIGS. 12A and 12B are cross-sectional diagrams illustrating the method of manufacturing the semiconductor device according to the second modification of the embodiment;

FIG. 13 is a cross-sectional diagram illustrating the method of manufacturing the semiconductor device according to the second modification of the embodiment;

FIG. 14 is a flowchart illustrating a method of manufacturing a semiconductor device according to a third modification of the embodiment;

FIG. 15 is a cross-sectional diagram illustrating the method of manufacturing the semiconductor device according to the third modification of the embodiment;

FIG. 16 is a cross-sectional diagram illustrating the method of manufacturing the semiconductor device according to the third modification of the embodiment;

FIGS. 17A and 17B are cross-sectional diagrams illustrating warpage of a substrate according to the third modification of the embodiment;

FIG. 18 is a flowchart illustrating a method of manufacturing a semiconductor device according to a fourth modification of the embodiment;

FIG. 19 is a cross-sectional diagram illustrating the method of manufacturing the semiconductor device according to the fourth modification of the embodiment; and

FIG. 20 is a cross-sectional diagram illustrating the method of manufacturing the semiconductor device according to the fourth modification of the embodiment.

### DETAILED DESCRIPTION

In general, according to one embodiment, there is provided a method of manufacturing a semiconductor device. The method comprises radically oxidizing a first film by using a plasma generated by a treatment gas including a hydrogen isotope gas.

Exemplary embodiments of a method of manufacturing a semiconductor device will be explained below in detail with reference to the accompanying drawings. The present invention is not limited to the following embodiments.

### Embodiment

In a method of manufacturing a semiconductor device according to the embodiment, a predetermined film is deposited on or above a substrate, and the deposited predetermined film is radically oxidized, but the device for efficiently performing radical oxidation is provided.

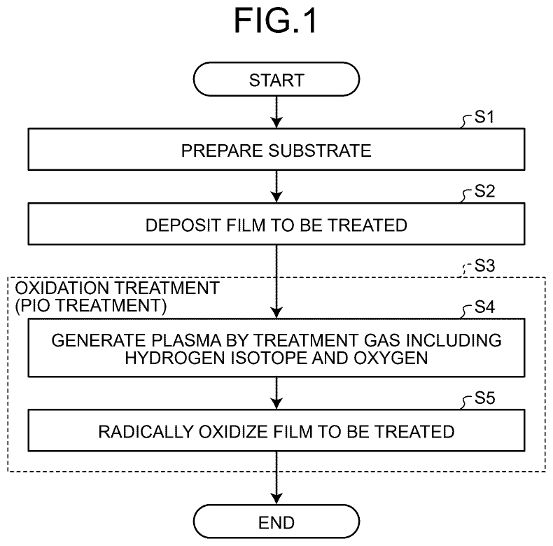

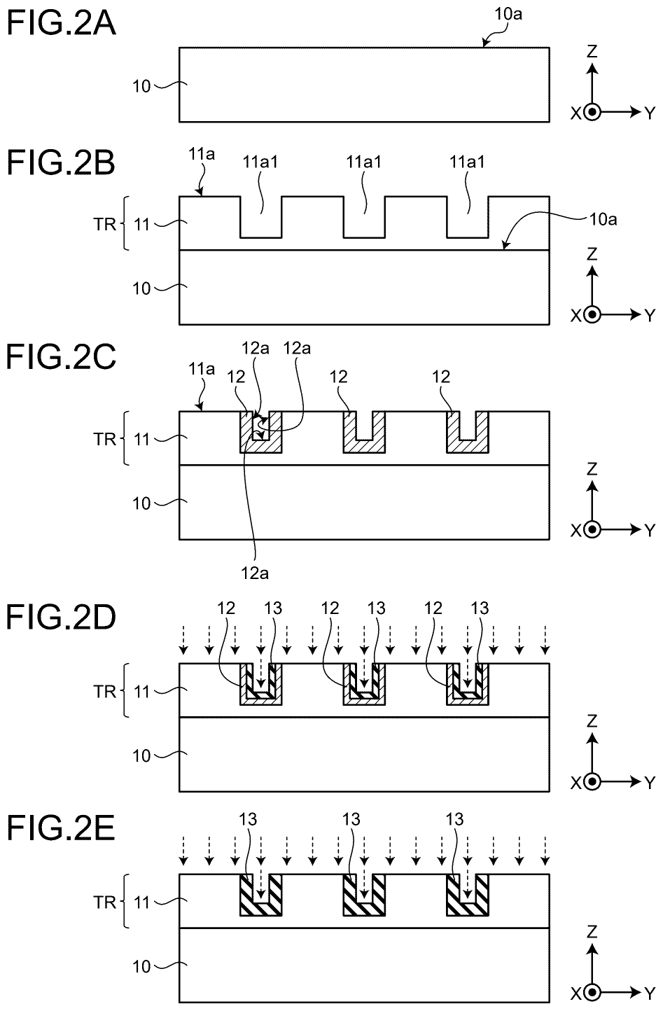

A method of manufacturing a semiconductor device 100 may be performed as illustrated in FIGS. 1 and 2A to 2E. FIG. 1 is a flowchart illustrating the method of manufacturing the semiconductor device 100. Hereinafter, a direction perpendicular to a main surface 10a of a substrate 10 is referred to as a Z direction, and two directions perpendicular to each other in a plane perpendicular to the Z direction are referred to as an X direction and a Y direction. FIGS. 2A to 2E are YZ cross-sectional diagrams illustrating the method of manufacturing the semiconductor device 100, respectively.

The substrate 10 illustrated in FIG. 2A is prepared (S1). The substrate 10 has a substantially disk shape, and has a substantially circular shape in an XY plan view. The substrate 10 can be formed of a material containing a semiconductor (for example, silicon) as a main component. The substrate 10 has the main surface 10a on the +Z side.

When the substrate 10 is prepared, a high aspect structure TR illustrated in FIG. 2B is formed on or above (+Z side) the main surface 10a of the substrate 10. FIG. 2B exemplifies a case where the high aspect structure TR is formed on the main surface 10a of the substrate 10.

A film 11 is deposited on or above the main surface 10a of the substrate 10 by a chemical vapor deposition (CVD) method, a sputtering method, or the like. The film 11 may be formed of an insulator. A resist pattern PR having openings corresponding to holes 11al is formed on the main surface 11a of the film 11. Etching is performed under a condition of anisotropic processing by using the resist pattern PR as a mask by a reactive ion etching (RIE) method or the like. As a result, the holes 11al having a high aspect ratio in a cross section including the Z axis are formed in the film 11. The high aspect ratio indicates that an aspect ratio (=depth of hole/width of hole bottom surface) is larger than 1. That is, the high aspect structure TR in which the holes 11a1 having a high aspect ratio are formed in the film 11 is obtained.

When the high aspect structure TR is formed, a film to be treated 12 illustrated in FIG. 2C is deposited on side surfaces and a bottom surface of the holes 11a1 (S2).

The film to be treated 12 is deposited on the film 11 by a CVD method, a sputtering method, or the like. In the deposited film to be treated 12, a portion covering the main surface 11a of the film 11 is removed by the RIE method or the like, and portions covering the side surfaces and the bottom surface of the holes 11al are left.

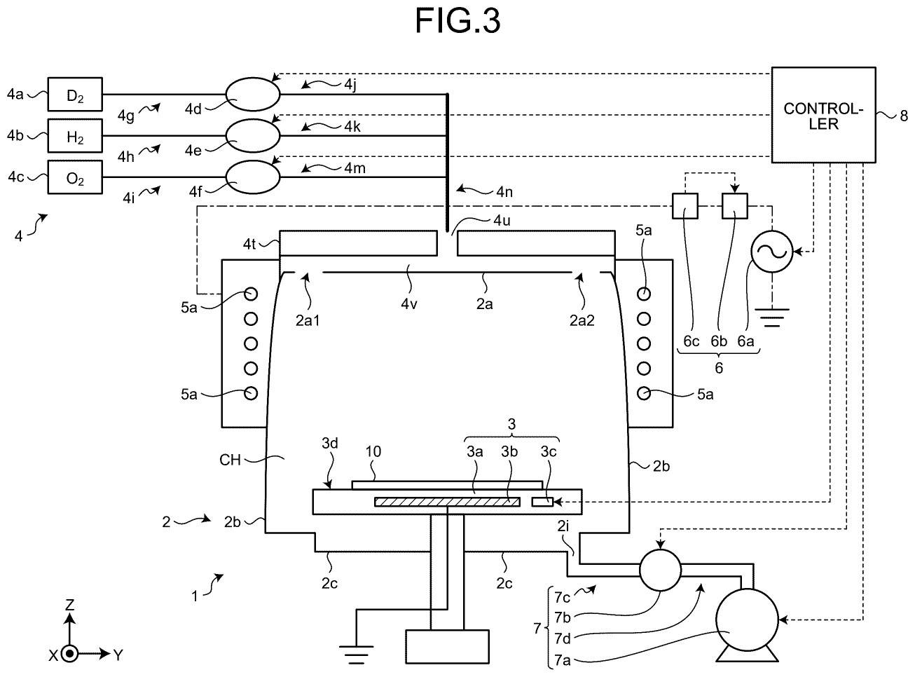

When the film to be treated 12 is deposited, the substrate 10 is carried into the substrate treatment apparatus 1 as illustrated in FIG. 3, and the film to be treated 12 is subjected to oxidation treatment (S3). FIG. 3 is a diagram illustrating a configuration of the substrate treatment apparatus 1 used in the method of manufacturing the semiconductor device 100.

The oxidation treatment (S3) may be performed by radically oxidizing the film to be treated 12 using a plasma generated by a treatment gas including a hydrogen isotope gas and an oxygen gas in the substrate treatment apparatus 1. The radical oxidation treatment using a plasma is isotropic treatment, and is referred to as plasma isotropic oxidation (PIO) treatment.

The substrate treatment apparatus 1 includes a vacuum container 2, a stage 3, a gas supply system 4, an electrode 5, a power supply unit 6, an exhaust system 7, and a controller 8.

The controller 8 can integrally control each unit of the substrate treatment apparatus 1.

A treatment chamber CH is formed inside the vacuum container 2. The treatment chamber CH is a chamber for generating a plasma PL therein. The vacuum container 2 has an upper wall 2a, side walls 2b, and a bottom wall 2c. The upper wall 2a is disposed on the +Z side, and the bottom wall 2c is disposed on the −Z side. The upper wall 2a may have slits 2a1 and 2a2 at positions outside in the XY direction. The bottom wall 2c may have a hole 2i at an arbitrary position.

The stage 3 is disposed in the treatment chamber CH. The stage 3 may be disposed in the vicinity of the bottom wall 2c in the treatment chamber CH. The stage 3 includes a main body portion 3a, an electrode 3b, and a heater 3c. The main body portion 3a extends in a plate shape or a disk shape in the XY direction. The main body portion 3a can be formed of an insulator. The +Z-side surface of the main body portion 3a forms a placement surface 3d. The substrate 10 can be placed on the placement surface 3d. Each of the electrode 3b and the heater 3c may be embedded in the main body portion 3a. The electrode 3b extends in a plate shape or a disk shape in the XY direction. The electrode 3b may be formed of a conductive material. The electrode 3b can be coupled to a ground potential via wiring. The heater 3c can heat the substrate 10 via the main body portion 3a under the control of the controller 8. Although not illustrated, the stage 3 may have a mechanism for adsorbing the substrate 10.

The gas supply system 4 can supply a treatment gas including a hydrogen isotope gas and an oxygen gas toward the stage 3 in the treatment chamber CH. The hydrogen isotope gas may be a deuterium gas (D₂) or a tritium gas (T₂). Hereinafter, a case where the hydrogen isotope gas is a deuterium gas will be mainly described, but the following description is similarly applicable to a case where the hydrogen isotope gas is a tritium gas.

The gas supply system 4 includes gas cylinders 4a to 4c, adjustment valves 4d to 4f, gas pipes 4g to 4n, and a lid body 4t. The gas cylinders 4a, 4b, and 4c store a deuterium gas (D₂), a light hydrogen gas (H₂), and an oxygen gas (O₂), respectively. The gas cylinder 4c stores, for example, ¹⁶O₂ gas. The lid body 4t has a gas introduction port 4u. The gas cylinders 4a to 4c communicate with the gas pipes 4g to 4i, respectively. The lid body 4t covers the upper wall 2a to be separated in the Z direction, and forms a buffer chamber 4v. The buffer chamber 4v communicates with the gas introduction port 4u on the +Z side, and communicates with the slits 2al and 2a2 on the −Z side. The adjustment valves 4d to 4f are disposed between the gas pipes 4g to 4n, and can be opened and closed and an opening degree thereof can be controlled by the controller 8.

The electrode 5 is disposed outside the treatment chamber CH at a position separated from the stage 3. The electrode 5 may be disposed in a portion on the +Z side of the side wall 2b. The electrode 5 includes coils 5a. The coils 5a may be wound around portions of the side walls 2b on the +Z side.

The power supply unit 6 can supply radio-frequency power to the electrode 5. The power supply unit 6 includes a radio-frequency power supply 6a, a matching device 6b, and a sensor 6c. The radio-frequency power supply 6a can supply radio-frequency power to the electrode 5 under the control of the controller 8. The sensor 6c monitors information of a radio-frequency traveling wave or reflected wave to be supplied, and supplies a monitoring result to the matching device 6b. The matching device 6b performs impedance matching so that the power of the reflected wave is reduced according to the monitoring result of the sensor 6c.

The exhaust system 7 can decompress the inside of the treatment chamber CH and adjust the pressure in the treatment chamber CH. The exhaust system 7 includes a vacuum pump 7a, an adjustment valve 7b, and vacuum pipes 7c and 7d. The vacuum pump 7a can be operated under the control of the controller 8. The adjustment valve 7b is disposed between the vacuum pipes 7c and 7d, and can be opened and closed and its opening degree can be controlled by the controller 8.

In the substrate treatment apparatus 1, the controller 8 applies a radio-frequency voltage between the electrode 3b and the electrode 5, and generates a plasma PL in the treatment chamber CH by a treatment gas including a hydrogen isotope gas (for example, D₂ gas) and an oxygen gas (O₂ gas) (S4).

For example, when the substrate 10 is placed on the placement surface 3d of the stage 3, the controller 8 raises the temperature of the substrate 10. The controller 8 may control the heater 3c to heat the substrate 10 to a temperature of 300° C. or more and 800° C. or less.

When the temperature of the substrate 10 is lower than 300° C., there is a possibility that a film formation rate of radical oxidation falls below an allowable level. When the temperature of the substrate 10 exceeds 800° C., there is a possibility that thermal oxidation of the film to be treated 12 is mixed in addition to radical oxidation, and it becomes difficult to control the film formation rate.

In parallel with the temperature rise of the substrate 10, the controller 8 operates the vacuum pump 7a, controls the opening degree of the adjustment valve 7b so that the pressure of the treatment chamber CH becomes 50 Pa or more and 300 Pa or less, and decompresses the inside of the treatment chamber CH via the vacuum pipes 7c and 7d.

It should be noted that, when the pressure in the treatment chamber CH is lower than 50 Pa, there is a possibility that an oxidation rate falls below an allowable level. When the pressure in the treatment chamber CH exceeds 300 Pa, there is a possibility that a plasma is not generated in the treatment chamber CH.

The controller 8 starts supplying a treatment gas including a hydrogen isotope gas (for example, D₂ gas) and an oxygen gas (O₂ gas) to the treatment chamber CH. The controller 8 opens the adjustment valves 4d and 4f while keeping the adjustment valve 4e closed. As a result, a hydrogen isotope gas (for example, D₂ gas) and an oxygen gas (O₂ gas) are introduced from the gas cylinders 4a and 4c into the gas pipe 4n via the gas pipes 4g, 41, 4j, and 4m, and mixed in the gas pipe 4n to become a treatment gas including a hydrogen isotope gas (for example, D₂ gas) and an oxygen gas (O₂ gas). The treatment gas is introduced from the gas pipe 4n into the buffer chamber 4v via the gas introduction port 4u. The treatment gas in the buffer chamber 4v is supplied from the slits 2al and 2a2 toward the stage 3 in the treatment chamber CH.

At this time, the controller 8 continues to control the opening degree of the adjustment valve 7b so that the pressure in the treatment chamber CH becomes 50 Pa or more and 300 Pa or less. In addition, the controller 8 controls the opening degrees of the adjustment valves 4d and 4f so that the flow rate ratio of the flow rate of the hydrogen isotope gas (for example, D₂ gas) to the flow rate of the treatment gas is 5% or more and 95% or less.

It should be noted that, when the flow rate ratio of the hydrogen isotope gas is lower than 5%, there is a possibility that a step coverage of an oxide film formed by radical oxidation falls below an allowable level. When the flow rate ratio of the hydrogen isotope gas exceeds 95%, there is a possibility that the step coverage of the oxide film formed by radical oxidation falls below an allowable level.

When the pressure in the treatment chamber CH is stabilized, the controller 8 starts supplying radio-frequency power from the power supply unit 6 to the electrode 5. As a result, a radio-frequency voltage is applied between the electrode 3b and the electrode 5, and an induction magnetic field is formed in the treatment chamber CH. The hydrogen isotope gas (for example, D₂ gas) and the oxygen gas (O₂ gas) included in the treatment gas are plasma-excited respectively, and for example, a donut-shaped plasma PL is formed. The plasma PL may be a plasma having a low electrical potential. The D₂ gas and the O₂ gas are dissociated by the plasma PL respectively, and reactive species such as oxidation radicals such as hydroxy radical OH⁺, deuterium ions, and oxygen ions are generated. Since the electrical potential of the plasma PL is low, deuterium ions and oxygen ions are not accelerated, and oxidation radicals and the like in the treatment gas are substantially uniformly supplied to the vicinity of an exposed surface 12a of the film to be treated 12 of the substrate 10.

As a result, the film to be treated 12 is radically oxidized (S5). As illustrated in FIG. 2D, the radical oxidation may be performed in the vicinity of the exposed surface 12a in the film to be treated 12, and a portion in the vicinity of the exposed surface 12a in the film to be treated 12 may be replaced with an oxide film 13. Alternatively, as illustrated in FIG. 2E, the radical oxidation may be performed on the entire film to be treated 12, and the entire film to be treated 12 may be replaced with the oxide film 13. Dotted arrows in FIGS. 2D and 2E indicate that oxidation radicals and ions in the treatment gas are substantially uniformly supplied to the vicinity of the exposed surface 12a of the film to be treated 12.

Then, a predetermined process is further performed on the substrate 10 illustrated in FIG. 2D or 2E, and the semiconductor device 100 is manufactured.

As described above, in the embodiment, in the method of manufacturing the semiconductor device 100, the film to be treated 12 is radically oxidized by using the plasma generated by the treatment gas including the hydrogen isotope gas and the oxygen gas. As a result, radical oxidation can be efficiently performed as compared with a case where the film to be treated 12 is radically oxidized by using a plasma generated by a treatment gas including a hydrogen gas and an oxygen gas.

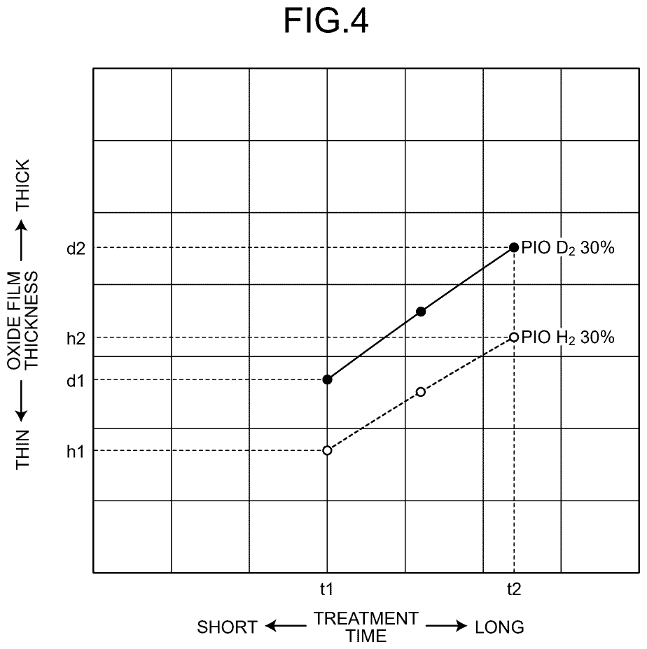

For example, when the substrate treatment apparatus 1 radically oxidizes the film to be treated 12 by using a plasma generated by a treatment gas including a hydrogen gas and an oxygen gas at a flow rate ratio of 30%:70%, a film thickness of the oxide film 13 according to a treatment time changes as indicated by a dotted line in FIG. 4. FIG. 4 is a diagram illustrating the change in the oxide film thickness according to the treatment time (in a case of a flow rate ratio of 30%). In a treatment time t1, the oxide film 13 is formed with a film thickness h1, and in the treatment time t2(>t1), the oxide film 13 is formed with a film thickness h2(>h1).

On the other hand, when the substrate treatment apparatus 1 radically oxidizes the film to be treated 12 by using a plasma generated by a treatment gas including a D₂ gas and an oxygen gas at a flow rate ratio of 30%:70%, the film thickness of the oxide film 13 according to the treatment time changes as indicated by a solid line in FIG. 4. In the treatment time t1, the oxide film 13 is formed with a film thickness d1, and in the treatment time t2, the oxide film 13 is formed with a film thickness d2(>d1).

A film formation amount in each treatment time is larger in a case of using a plasma generated by a treatment gas including a hydrogen isotope gas and an oxygen gas than in a case of using a plasma generated by a treatment gas including a hydrogen gas and an oxygen gas. When viewed at the treatment time t1, the film thickness d1 is larger than the film thickness h1. When viewed at the treatment time t2, the film thickness d2 is larger than the film thickness h2.

A film formation rate is larger in the case of using a plasma generated by a treatment gas including a hydrogen isotope gas and an oxygen gas than in the case of using a plasma generated by a treatment gas including a hydrogen gas and an oxygen gas. When viewed in a period of the treatment time t1 to t2, a slope (d2−d1)/(t2−t1) of the solid line is larger than a slope (h2−h1)/(t2−t1) of the dotted line.

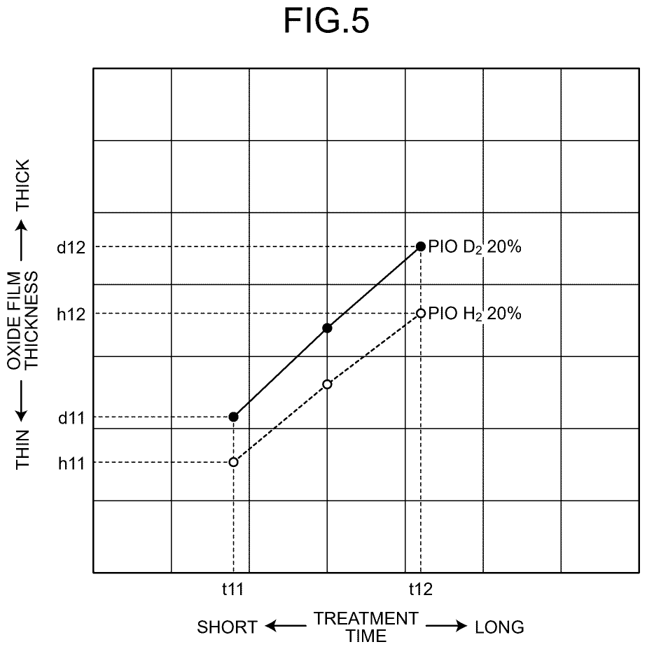

Alternatively, when the substrate treatment apparatus 1 radically oxidizes the film to be treated 12 by using a plasma generated by a treatment gas including a hydrogen gas and an oxygen gas at a flow rate ratio of 20%:80%, the film thickness of the oxide film 13 according to the treatment time changes as indicated by a dotted line in FIG. 5. FIG. 5 is a diagram illustrating a change in the oxide film thickness according to the treatment time (in a case of a flow rate ratio of 20%). In a treatment time t11, the oxide film 13 is formed with a film thickness h11, and in a treatment time t12(>t11), the oxide film 13 is formed with a film thickness h12(>h11).

On the other hand, when the substrate treatment apparatus 1 radically oxidizes the film to be treated 12 by using a plasma generated by a treatment gas including a De gas and an oxygen gas at a flow rate ratio of 20%:80%, the film thickness of the oxide film 13 according to the treatment time changes as indicated by a solid line in FIG. 5. In the treatment time t11, the oxide film 13 is formed with a film thickness d11, and in the treatment time t12, the oxide film 13 is formed with a film thickness d12(>d11).

A film formation amount in each treatment time is larger in a case of using a plasma generated by a treatment gas including a hydrogen isotope gas and an oxygen gas than in a case of using a plasma generated by a treatment gas including a hydrogen gas and an oxygen gas. When viewed at the treatment time t11, the film thickness d11 is larger than the film thickness h11. When viewed at the treatment time t12, the film thickness d12 is larger than the film thickness h12.

A film formation rate is larger in the case of using a plasma generated by a treatment gas including a hydrogen isotope gas and an oxygen gas than in the case of using a plasma generated by a treatment gas including a hydrogen gas and an oxygen gas. When viewed in a period of the treatment time t11 to t12, a slope (d12−d11)/(t12−t11) of the solid line is larger than a slope (h12−h11)/(t12−t11) of the dotted line.

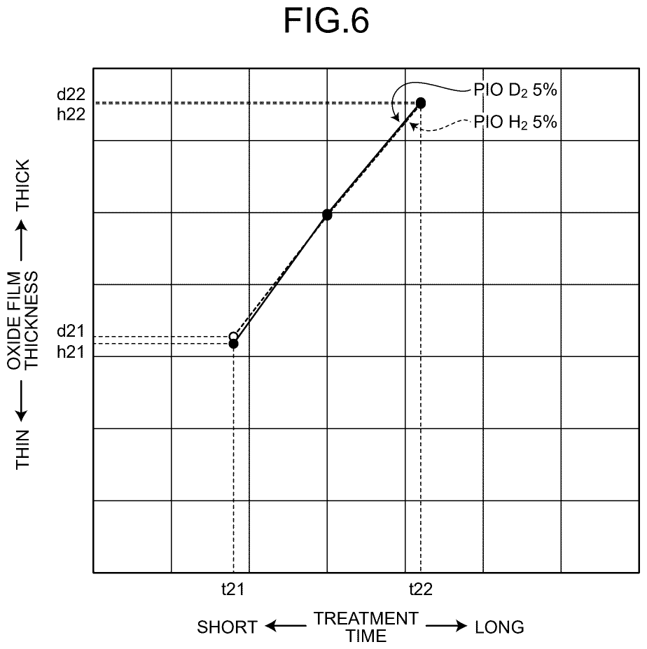

Alternatively, when the substrate treatment apparatus 1 radically oxidizes the film to be treated 12 by using a plasma generated by a treatment gas including a hydrogen gas and an oxygen gas at a flow rate ratio of 5%:95%, the film thickness of the oxide film 13 according to the treatment time changes as indicated by a dotted line in FIG. 6. FIG. 6 is a diagram illustrating a change in the oxide film thickness according to the treatment time (in a case of a flow rate ratio of 5%). In a treatment time t21, the oxide film 13 is formed with a film thickness h21, and in a treatment time t22(>t21), the oxide film 13 is formed with a film thickness h22(>h21).

On the other hand, when the substrate treatment apparatus 1 radically oxidizes the film to be treated 12 by using a plasma generated by a treatment gas including a De gas and an oxygen gas at a flow rate ratio of 58:95%, the film thickness of the oxide film 13 according to the treatment time changes as indicated by a solid line in FIG. 6. In the treatment time t21, the oxide film 13 is formed with a film thickness d21, and in the treatment time t22, the oxide film 13 is formed with a film thickness d22(>d21).

A film formation amount in each treatment time is substantially the same between the case of using a plasma generated by a treatment gas including a hydrogen gas and an oxygen gas and the case of using a plasma generated by a treatment gas including a hydrogen isotope gas and an oxygen gas. When viewed at the treatment time t21, the film thickness d21 is substantially the same as the film thickness h21. When viewed at the treatment time t22, the film thickness d22 is substantially the same as the film thickness h22.

The film formation rate is substantially the same between the case of using a plasma generated by a treatment gas including a hydrogen gas and an oxygen gas and the case of using a plasma generated by a treatment gas including a hydrogen isotope gas and an oxygen gas. When viewed in the period of the treatment time t11 to t12, the slope (d12−d11)/(t12−t11) of the solid line is substantially the same as the slope (h12−h11)/(t12−t11) of the dotted line.

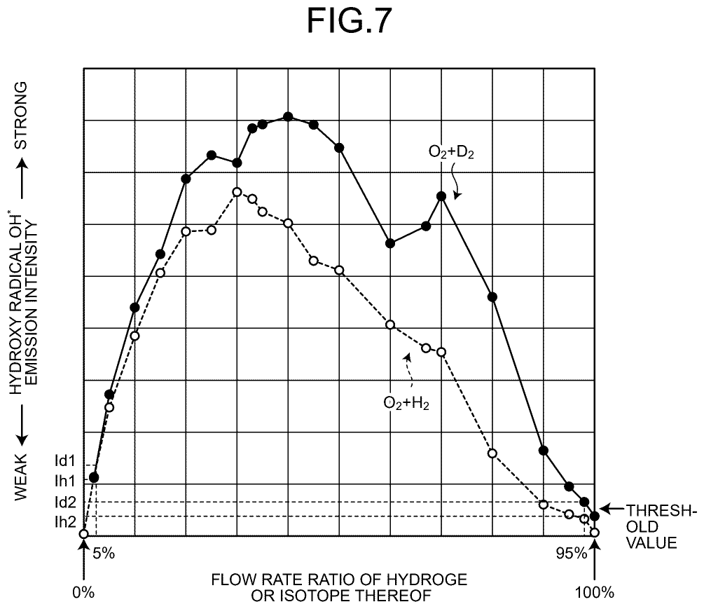

Alternatively, when the substrate treatment apparatus 1 radically oxidizes the film to be treated 12 by using a plasma generated by a treatment gas including a hydrogen gas at a flow rate ratio of 0% to 100%, hydroxy radical OH⁺ emission intensity is as indicated by a dotted line in FIG. 7. FIG. 7 is a diagram illustrating a change in hydroxy radical OH⁺ emission intensity according to a flow rate ratio of hydrogen or an isotope thereof. The hydroxy radical OH⁺ emission intensity correlates with a step coverage of the oxide film 13. The fact that light emission in a predetermined spectral band (for example, a spectral band having a wavelength of 306 to 315 nm) is detected at a portion oxidized by the hydroxy radical OH⁺ in the film to be treated 11 is used. It is estimated that the step coverage of the oxide film 13 is better as the hydroxy radical OH⁺ emission intensity is stronger. When the change of the dotted line in FIG. 7 is viewed, a change in a mountain shape exceeding a threshold value is generally indicated at 5% or more and 95% or less, and it is estimated that, by setting the flow rate ratio of the hydrogen gas to 5% or more and 95% or less, the emission intensity is such that the step coverage of the oxide film 13 is approximately at an allowable level. The threshold value may be experimentally determined in advance as corresponding to the allowable level of the step coverage of the oxide film 13.

On the other hand, when the substrate treatment apparatus 1 radically oxidizes the film to be treated 12 by using a plasma generated by a treatment gas including a De gas at a flow rate ratio of 0% to 100%, the hydroxy radical OH⁺ emission intensity is as indicated by a solid line in FIG. 7. When the change of the solid line in FIG. 7 is viewed, a change in a mountain shape exceeding a threshold value is generally indicated at 5% or more and 95% or less, and it is estimated that, by setting the flow rate ratio of the hydrogen gas to 58 or more and 95% or less, the emission intensity is such that the step coverage of the oxide film 13 is approximately at an allowable level.

The hydroxy radical OH⁺ emission intensity at the flow rate ratio of 5% or more and 95% or less is larger in the case of using a plasma generated by a treatment gas including a hydrogen isotope gas and an oxygen gas than in the case of using a plasma generated by a treatment gas including a hydrogen gas and an oxygen gas. When viewed at the flow rate ratio of 5%, a value Id1 of the solid line is larger than a value Ih1 of the dotted line. When viewed at the flow rate ratio of 95%, a value Id2 of the solid line is larger than a value Ih2 of the dotted line. When viewed at the flow rate ratio range of 5% or more and 95% or less, a solid curve is on the higher emission intensity side than a dotted curve. As a result, it is estimated that the step coverage of the oxide film 13 by the radical oxidation can be improved in the case of using a plasma generated by a treatment gas including a hydrogen isotope gas and an oxygen gas as compared with the case of using a plasma generated by a treatment gas including a hydrogen gas and an oxygen gas.

It should be noted that the treatment gas used in S4 may be a mixed gas of a hydrogen gas, a hydrogen isotope gas, and an oxygen gas. For example, in S4 indicated in FIG. 1, the controller 8 starts supplying a treatment gas including a hydrogen gas (H₂ gas), a hydrogen isotope gas (for example, D₂ gas), and an oxygen gas (O₂ gas) to the treatment chamber CH. The controller 8 opens the adjustment valves 4d, 4e, and 4f. As a result, a hydrogen gas (H₂ gas), a hydrogen isotope gas (for example, D₂ gas), and an oxygen gas (O₂ gas) are introduced from the gas cylinders 4a, 4b, and 4c into the gas pipe 4n via the gas pipes 4g, 4 h, 41, 4j, 4k, and 4m, and are mixed in the gas pipe 4n to become a treatment gas including a hydrogen gas (H₂ gas), a hydrogen isotope gas (for example, D₂ gas), and an oxygen gas (O₂ gas). The treatment gas is introduced from the gas pipe 4n into the buffer chamber 4v via the gas introduction port 4u. The treatment gas in the buffer chamber 4v is supplied from the slits 2a1 and 2a2 toward the stage 3 in the treatment chamber CH. At this time, the controller 8 controls the opening degrees of the adjustment valves 4d, 4e, and 4f so that the flow rate ratio of the flow rate of the hydrogen isotope gas (for example, D₂ gas) to the flow rate of the treatment gas is 5% or more and 95% or less. Also in this case, the step coverage of the oxide film 13 by the radical oxidation can be improved by setting the flow rate ratio of the hydrogen isotope gas to the flow rate of the treatment gas to 5% or more and 95% or less.

The treatment gas used in S4 may further include a rare gas such as a helium gas or an argon gas. The treatment gas may be a mixed gas of a hydrogen isotope gas, an oxygen gas, and a rare gas, or may be a mixed gas of a hydrogen gas, a hydrogen isotope gas, an oxygen gas, and a rare gas. Even in this case, the step coverage of the oxide film 13 by the radical oxidation can be improved by setting the flow rate ratio of the hydrogen isotope gas to the flow rate of the treatment gas to 5% or more and 95% or less.

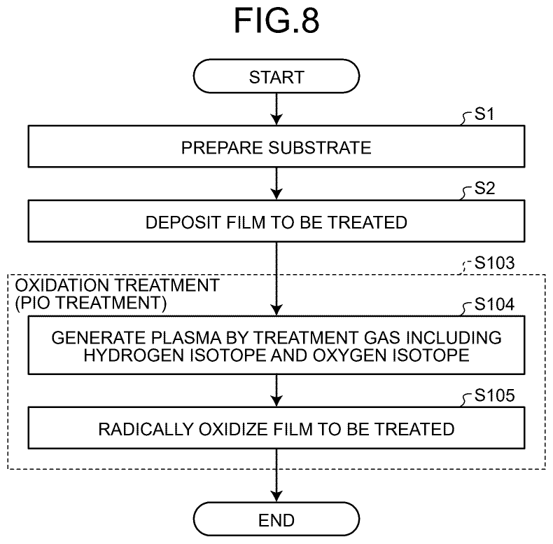

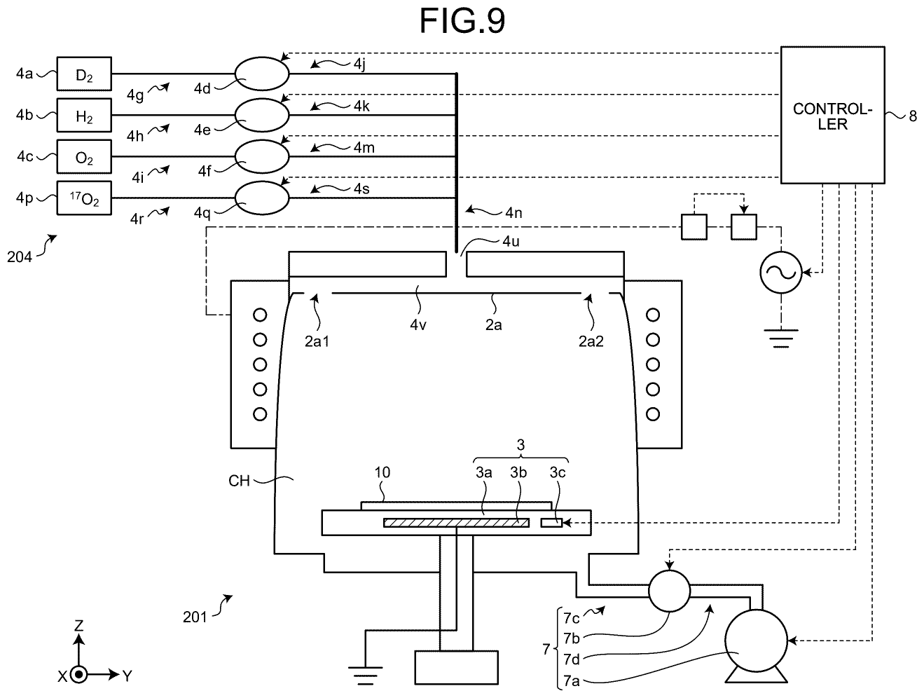

Alternatively, as a first modification of the embodiment, as illustrated in FIG. 8, oxidation treatment (S103) may be performed by radically oxidizing the film to be treated 12 by using a plasma generated by a treatment gas including a hydrogen isotope gas and an oxygen isotope gas in a substrate treatment apparatus 201 illustrated in FIG. 9. FIG. 8 is a flowchart illustrating a method of manufacturing the semiconductor device 100 according to the first modification of the embodiment. FIG. 9 is a diagram illustrating a configuration of the substrate treatment apparatus 201 used in the method of manufacturing the semiconductor device 100 according to the first modification of the embodiment.

The substrate treatment apparatus 201 includes a gas supply system 204 instead of the gas supply system 4 (see FIG. 3). The gas supply system 204 can supply a treatment gas including a hydrogen isotope gas and an oxygen isotope gas toward the stage 3 in the treatment chamber CH. The hydrogen isotope gas may be a deuterium gas (D₂) or a tritium gas (T₂). The oxygen isotope gas may be an oxygen 17 (¹⁷O₂) gas or an oxygen 18 (¹⁸O₂) gas. Hereinafter, a case where the hydrogen isotope gas is a deuterium gas and the oxygen isotope gas is a ¹⁷O₂ gas will be mainly described, but the following description is similarly applicable to a case where a specific example of the hydrogen isotope gas and a specific example of the oxygen isotope gas are other combinations.

The gas supply system 204 further includes a gas cylinder 4p, an adjustment valve 4q, and gas pipes 4r and 4s. The gas cylinder 4p stores a ¹⁷O₂ gas. The gas cylinder 4p communicates with the gas pipe 4r. The adjustment valve 4q is disposed between the gas pipes 4r and 4s, and can be opened and closed and its opening degree can be controlled by the controller 8.

In the substrate treatment apparatus 201, the controller 8 applies a radio-frequency voltage between the electrode 3b and the electrode 5, and generates a plasma PL in the treatment chamber CH by a treatment gas including a hydrogen isotope gas (for example, D₂ gas) and an oxygen isotope gas (for example, ¹⁷O₂ gas) (S104).

For example, when the substrate 10 is placed on the placement surface 3d of the stage 3, the controller 8 raises the temperature of the substrate 10. The controller 8 may control the heater 3c to heat the substrate 10 to a temperature of 300° C. or more and 800° C. or less.

In parallel with this, the controller 8 operates the vacuum pump 7a, controls the opening degree of the adjustment valve 7b so that the pressure in the treatment chamber CH becomes 50 Pa or more and 300 Pa or less, and decompresses the inside of the treatment chamber CH via the vacuum pipes 7c and 7d.

The controller 8 starts supplying a treatment gas including a hydrogen isotope gas (for example, D₂ gas) and an oxygen isotope gas (for example, ¹⁷O₂ gas) to the treatment chamber CH. The controller 8 opens the adjustment valves 4d and 4q while keeping the adjustment valves 4e and 4f closed. As a result, a hydrogen isotope gas (for example, D₂ gas) and an oxygen isotope gas (for example, ¹⁷O₂ gas) are introduced from the gas cylinders 4a and 4p into the gas pipe 4n via the gas pipes 4g, 4r, 4j, and 4s, and are mixed in the gas pipe 4n to become a treatment gas including a hydrogen isotope gas (for example, D₂ gas) and an oxygen isotope gas (for example, ¹⁷O₂ gas). The treatment gas is introduced from the gas pipe 4n into the buffer chamber 4v via the gas introduction port 4u. The treatment gas in the buffer chamber 4v is supplied from the slits 2a1 and 2a2 toward the stage 3 in the treatment chamber CH.

At this time, the controller 8 continues to control the opening degree of the adjustment valve 7b so that the pressure in the treatment chamber CH becomes 50 Pa or more and 300 Pa or less. In addition, the controller 8 controls the opening degrees of the adjustment valves 4d and 4q so that the flow rate ratio of the flow rate of the hydrogen isotope gas (for example, D₂ gas) to the flow rate of the treatment gas is 5% or more and 95% or less.

When the pressure in the treatment chamber CH is stabilized, the controller 8 starts supplying radio-frequency power from the power supply unit 6 to the electrode 5. As a result, a radio-frequency voltage is applied between the electrode 3b and the electrode 5, and an induction magnetic field is formed in the treatment chamber CH. The hydrogen isotope gas (for example, D₂ gas) and the oxygen isotope gas (for example, ¹⁷O₂ gas) included in the treatment gas are plasma-excited, and for example, a donut-shaped plasma PL is formed. The plasma PL may be a plasma having a low electrical potential. The D₂ gas and the ¹⁷O₂ gas are dissociated by the plasma PL respectively, and reactive species such as oxidation radicals such as hydroxy radical OH⁺, deuterium ions, and oxygen ions are generated. Since the electrical potential of the plasma PL is low, deuterium ions and oxygen ions are not accelerated, and oxidation radicals and the like in the treatment gas are substantially uniformly supplied to the vicinity of an exposed surface 12a of the film to be treated 12 of the substrate 10.

As a result, the film to be treated 12 is radically oxidized (S105). As illustrated in FIG. 2D, the radical oxidation may be performed in the vicinity of the exposed surface 12a in the film to be treated 12, and a portion in the vicinity of the exposed surface 12a in the film to be treated 12 may be replaced with an oxide film 13. Alternatively, as illustrated in FIG. 2E, the radical oxidation may be performed on the entire film to be treated 12, and the entire film to be treated 12 may be replaced with the oxide film 13. Dotted arrows in FIGS. 2D and 2E indicate that oxidation radicals and ions in the treatment gas are substantially uniformly supplied to the vicinity of the exposed surface 12a of the film to be treated 12.

In this way, in the method of manufacturing the semiconductor device 100, the film to be treated 12 is radically oxidized by using the plasma generated by the treatment gas including the hydrogen isotope gas and the oxygen isotope gas. As a result, radical oxidation can be more efficiently performed as compared with a case where the film to be treated 12 is radically oxidized by using a plasma generated by a treatment gas including a hydrogen gas and an oxygen gas.

For example, the film formation rate can be larger in the case of using a plasma generated by a treatment gas including a hydrogen isotope gas and an oxygen isotope gas than in the case of using a plasma generated by a treatment gas including a hydrogen isotope gas and an oxygen gas.

Alternatively, the step coverage of the oxide film 13 can be larger in the case of using a plasma generated by a treatment gas including a hydrogen isotope gas and an oxygen isotope gas than in the case of using a plasma generated by a treatment gas including a hydrogen isotope gas and an oxygen gas.

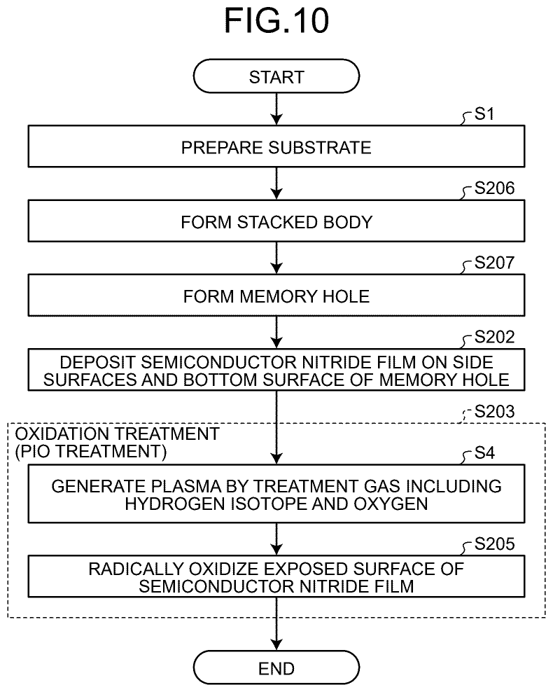

It should be noted that in the method of manufacturing the semiconductor device 100, the treatment gas used in S4 may be a mixed gas of a hydrogen gas, a hydrogen isotope gas, and an oxygen isotope gas, or may be a mixed gas of a hydrogen gas, a hydrogen isotope gas, an oxygen gas, and an oxygen isotope gas. For example, in S4 of FIG. 10, the controller 8 starts supplying a treatment gas including a hydrogen gas (H₂ gas), a hydrogen isotope gas (for example, D₂ gas), an oxygen gas (O₂ gas), and an oxygen isotope gas (for example, ¹⁷O₂ gas) to the treatment chamber CH. The controller 8 opens the adjustment valves 4d, 4e, 4f, and 4q. As a result, a hydrogen gas (H₂ gas), a hydrogen isotope gas (for example, D₂ gas), an oxygen gas (O₂ gas), and an oxygen isotope gas (for example, ¹⁷O₂ gas) are introduced from the gas cylinders 4a, 4b, 4c, and 4p into the gas pipe 4n via the gas pipes 4g, 4 h, 41, 4r, 4j, 4k, 4m, and 4s, mixed in the gas pipe 4n, and become a treatment gas including a hydrogen gas (H₂ gas), a hydrogen isotope gas (for example, D₂ gas), an oxygen gas (O₂ gas), and an oxygen isotope gas (for example, ¹⁷O₂ gas). The treatment gas is introduced from the gas pipe 4n into the buffer chamber 4v via the gas introduction port 4u. The treatment gas in the buffer chamber 4v is supplied from the slits 2a1 and 2a2 toward the stage 3 in the treatment chamber CH. The controller 8 controls the opening degrees of the adjustment valves 4d, 4e, 4f, and 4q so that the flow rate ratio of the flow rate of a hydrogen isotope gas (for example, D₂ gas) to the flow rate of the treatment gas is 5% or more and 95% or less. Also in this case, the step coverage of the oxide film 13 by the radical oxidation can be improved by setting the flow rate ratio of the hydrogen isotope gas to the flow rate of the treatment gas to 5% or more and 95% or less.

The treatment gas used in S4 may further include a rare gas such as a helium gas or an argon gas. The treatment gas may be a mixed gas of a hydrogen isotope gas, an oxygen isotope gas, and a rare gas, a mixed gas of a hydrogen gas, a hydrogen isotope gas, an oxygen isotope gas, and a rare gas, or a mixed gas of a hydrogen gas, a hydrogen isotope gas, an oxygen gas, an oxygen isotope gas, and a rare gas. Even in this case, the step coverage of the oxide film 13 by the radical oxidation can be improved by setting the flow rate ratio of the hydrogen isotope gas to the flow rate of the treatment gas to 5% or more and 95% or less.

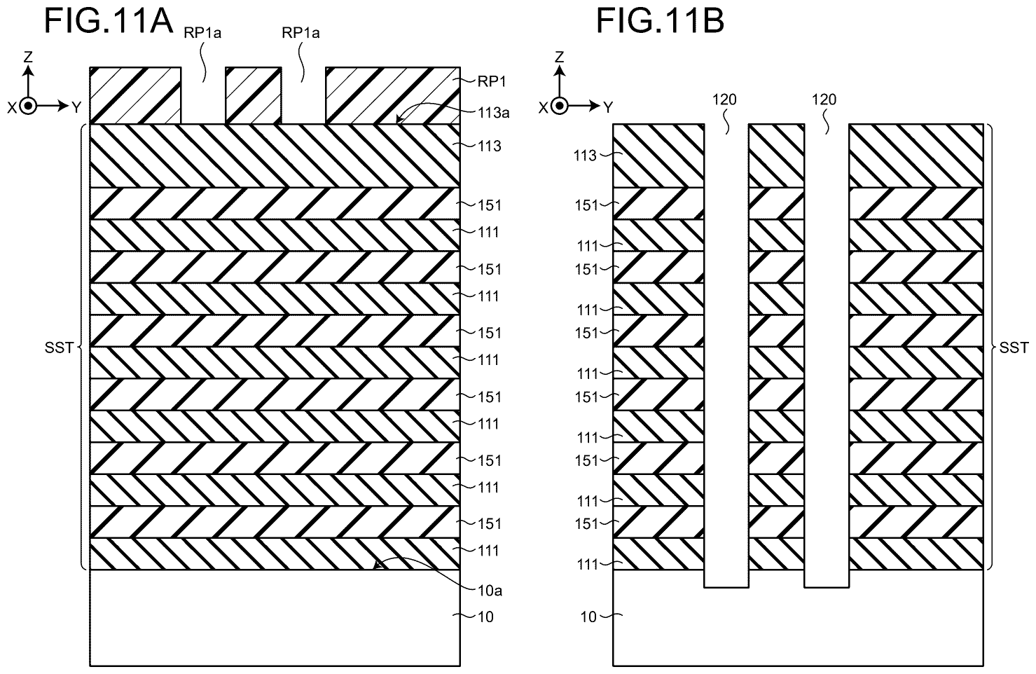

Alternatively, as a second modification of the embodiment, the idea of the embodiment may be applied to formation of a block insulating film in a method of manufacturing a semiconductor device 300 such as a three-dimensional memory. For example, the method of manufacturing the semiconductor device 300 may be performed as illustrated in FIGS. 10 to 13. FIG. 10 is a flowchart illustrating the method of manufacturing the semiconductor device 300 according to the second modification of the embodiment. FIGS. 11A, 11B, 12A, 12B, and 13 are YZ cross-sectional diagrams illustrating the method of manufacturing the semiconductor device 300.

When the substrate 10 is prepared (S1), a stacked body SST illustrated in FIG. 11A is formed on or above (+Z side) the main surface 10a of the substrate 10 (S206). FIG. 11A exemplifies a case where the stacked body SST is formed on the main surface 10a of the substrate 10.

Insulating layers 111 and sacrificial layers 151 are alternately and repeatedly stacked multiple times on the main surface 10a of the substrate 10. FIG. 11A exemplifies a case where the number of repetitions is six, but the number of repetitions is not limited to six and may be a larger number. The insulating layer 111 can be formed of a material containing a semiconductor oxide (for example, silicon oxide) as a main component. The sacrificial layer 151 is formed of a material capable of securing an etching selectivity to the insulating layer 111. The sacrificial layer 151 may be formed of a material containing a semiconductor nitride (for example, silicon nitride) as a main component. An insulating layer 113 is stacked on the sacrificial layer 151 closest to the Z side. The insulating layer 113 can be formed of a material containing a semiconductor oxide (for example, silicon oxide) as a main component. As a result, the stacked body SST in which the insulating layers 111 and the sacrificial layers 151 are alternately and repeatedly stacked multiple times and the insulating layer 113 is further stacked is obtained.

When the stacked body SST is obtained, memory holes 120 are formed in the stacked body SST (S207).

A resist pattern RP1 having openings RP1a corresponding to the memory holes 120 is formed on a main surface 113a of the insulating layer 113 on the most +Z side in the stacked body SST. Etching is performed by using the resist pattern RP1 as a mask by the RIE method or the like under the condition of anisotropic processing until reaching the substrate 10. As a result, as illustrated in FIG. 11B, the memory holes 120 extending in the Z direction through the stacked body SST and reaching the substrate 10 are formed in the stacked body SST.

Note that the memory hole 120 may be formed by alternately repeating the process illustrated in FIG. 11A and the process illustrated in FIG. 11B multiple times. As a result, the memory hole 120 having a high aspect ratio can be easily formed.

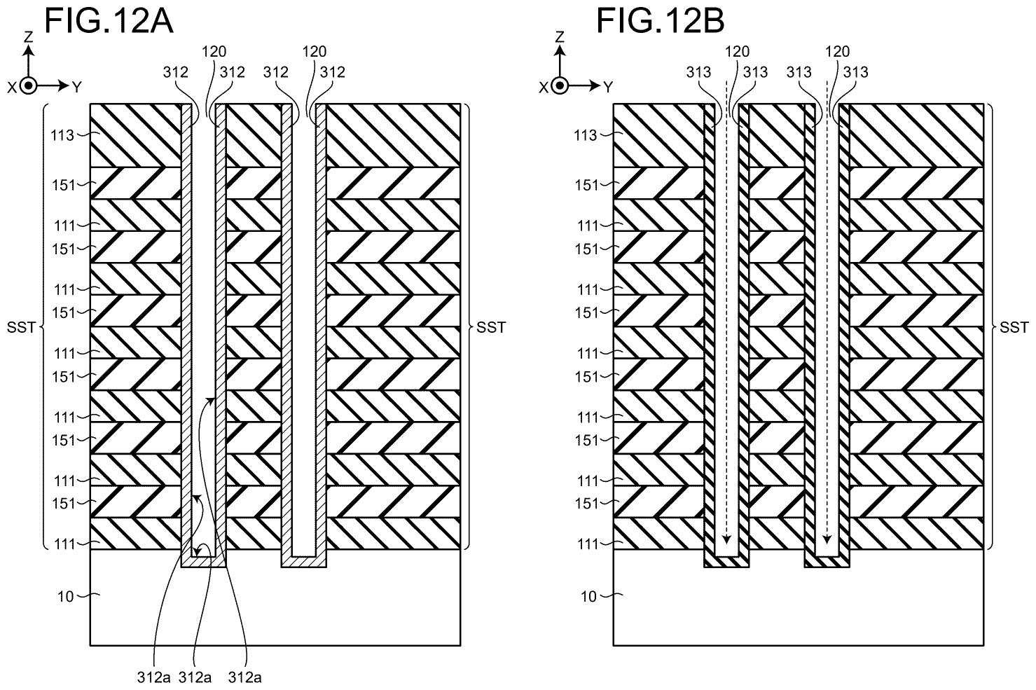

When the memory hole 120 is formed, as illustrated in FIG. 12A, a semiconductor nitride film 312 is deposited on side surfaces and a bottom surface of the memory hole 120 by the CVD method or the like (S202). The semiconductor nitride film 312 can be formed of a material containing silicon nitride as a main component.

When the semiconductor nitride film 312 is deposited, the substrate 10 is carried into the substrate treatment apparatus 1 (see FIG. 3), and the semiconductor nitride film 312 is subjected to oxidation treatment (S203).

The oxidation treatment (S203) may be performed by PIO treatment in which the semiconductor nitride film 312 is radically oxidized by using a plasma generated by a treatment gas including a hydrogen isotope gas and an oxygen gas in the substrate treatment apparatus 1.

In the substrate treatment apparatus 1, the controller 8 applies a radio-frequency voltage between the electrode 3b and the electrode 5, and generates a plasma PL in the treatment chamber CH by a treatment gas including a hydrogen isotope gas (for example, D₂ gas) and an oxygen gas (O₂ gas) (S4). By applying a radio-frequency voltage between the electrode 3b and the electrode 5, an induction magnetic field is formed in the treatment chamber CH. The hydrogen isotope gas (for example, D₂ gas) and the oxygen gas (O₂ gas) included in the treatment gas are plasma-excited respectively, and for example, a donut-shaped plasma PL is formed. The plasma PL may be a plasma having a low electrical potential. The D₂ gas and the O₂ gas are dissociated by the plasma PL respectively, and reactive species such as oxidation radicals such as hydroxy radical OH⁺, deuterium ions, and oxygen ions are generated. Since the electrical potential of the plasma PL is low, deuterium ions and oxygen ions are not accelerated, and oxidation radicals and the like in the treatment gas are substantially uniformly supplied to the vicinity of an exposed surface 312a of the semiconductor nitride film 312 through the memory hole 120.

As a result, the semiconductor nitride film 312 is radically oxidized (S205). The radical oxidation may be performed in the vicinity of the exposed surface 312a in the semiconductor nitride film 312, and a portion in the vicinity of the exposed surface 312a in the semiconductor nitride film 312 may be replaced with an oxide film 313. Alternatively, as illustrated in FIG. 12B, the radical oxidation may be performed on the entire semiconductor nitride film 312, and the entire semiconductor nitride film 312 may be replaced with the oxide film 313. Dotted arrows in FIG. 12B indicate that oxidation radicals and ions in the treatment gas are substantially uniformly supplied to the vicinity of the exposed surface 312a of the semiconductor nitride film 312. As a result, a block insulating film including the oxide film 313 is formed on the side surfaces and the bottom surface of the memory hole 120.

In the memory hole 120, a charge accumulation film and a tunnel insulating film are further deposited in order. The charge accumulation film may be formed of an insulator such as silicon nitride. The tunnel insulating film may be formed of an insulator such as silicon oxide. The block insulating film, the charge accumulation film, and the tunnel insulating film at a portion of the bottom surface of the memory hole 120 are selectively removed.

A semiconductor film is deposited on the side surfaces and the bottom surface of the memory hole 120. The semiconductor film may be formed of a material containing a semiconductor substantially free of impurities (for example, polysilicon) as a main component. The semiconductor film is subjected to heat treatment at a predetermined temperature, and the crystallinity of the semiconductor film is improved. Then, a core member is embedded in the memory hole 120. The core member may be formed of an insulator such as silicon oxide. As a result, columnar bodies penetrating the stacked body SST in the Z direction are formed.

The sacrificial layers 151 of the stacked body SST are removed. Insulating films are formed on the exposed surfaces of voids formed by the removal. The insulating film may be formed of an insulator such as aluminum oxide. Conductive layers 112 are further embedded in the voids. The conductive layer 112 may be formed of a material containing a conductive material (for example, a metal such as tungsten) as a main component. As a result, a stacked body SSTa in which the conductive layers 112 and the insulating layers 111 are alternately and repeatedly stacked and the insulating layer 113 is further stacked is formed.

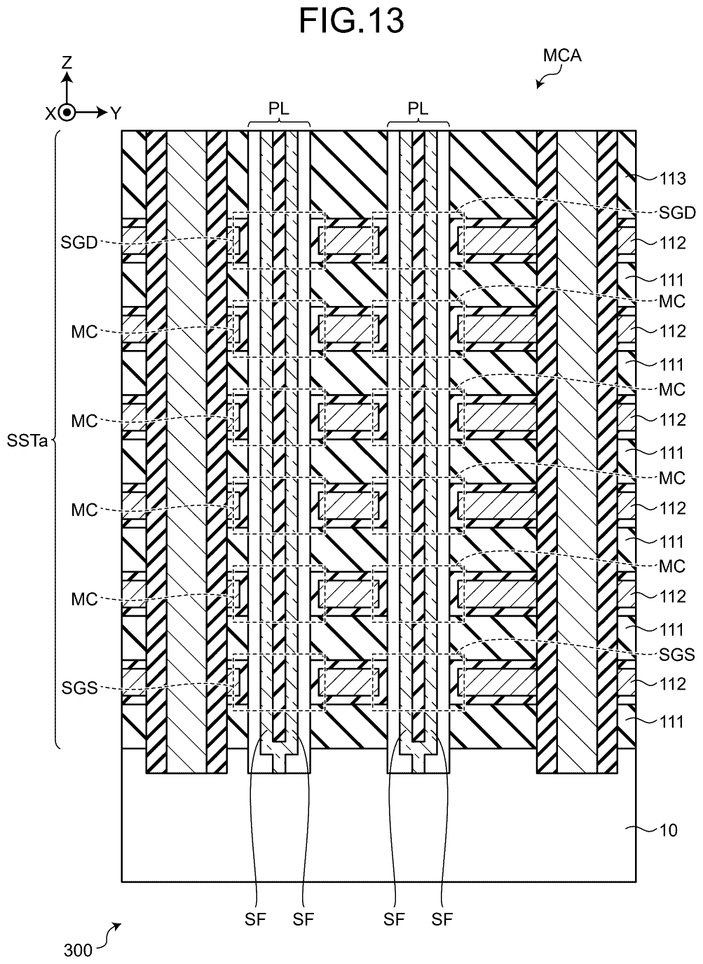

As a result, as illustrated in FIG. 13, a memory cell array structure MCA in which multiple memory cells MC are three-dimensionally arranged is formed. In the memory cell array structure MCA, the multiple memory cells MC and select gates SGS and SGD at both ends in the Z direction thereof are formed at multiple positions where the multiple conductive layers 112 and semiconductor films SF of multiple columnar bodies PL intersect in the stacked body SSTa. Note that a conductive region (not illustrated) disposed on the −Z side of the stacked body SSTa functions as a source region in the memory cell array structure MCA. The conductive layer 112 closest to the −Z side among the multiple conductive layers 112 functions as a source-side select gate line. The conductive layer 112 closest to the +Z side among the multiple conductive layers 112 functions as a drain-side select gate line. The remaining conductive layers 112 among the multiple conductive layers 112 each function as a word line.

That is, the semiconductor device 300 functioning as a three-dimensional memory is manufactured.

In this way, in the method of manufacturing the semiconductor device 300, the semiconductor nitride film 312 is radically oxidized by using a plasma generated by a treatment gas including a hydrogen isotope gas and an oxygen gas. As a result, radical oxidation can be efficiently performed as compared with a case where the semiconductor nitride film 312 is radically oxidized by using a plasma generated by a treatment gas including a hydrogen gas and an oxygen gas.

In addition, in the method of manufacturing the semiconductor device 300, the step coverage of the oxide film 313 can be easily improved by using the radical oxidation for the formation of the block insulating film, so that the insulating performance of the block insulating film to be formed can be improved. As a result, it is possible to suppress the occurrence of a back tunnel phenomenon in which charges from the conductive layer 112 as a word line tunnel through the block insulating film and are accumulated in the charge accumulation film. Therefore, in the semiconductor device 300, the operation reliability of the memory cells MC can be improved.

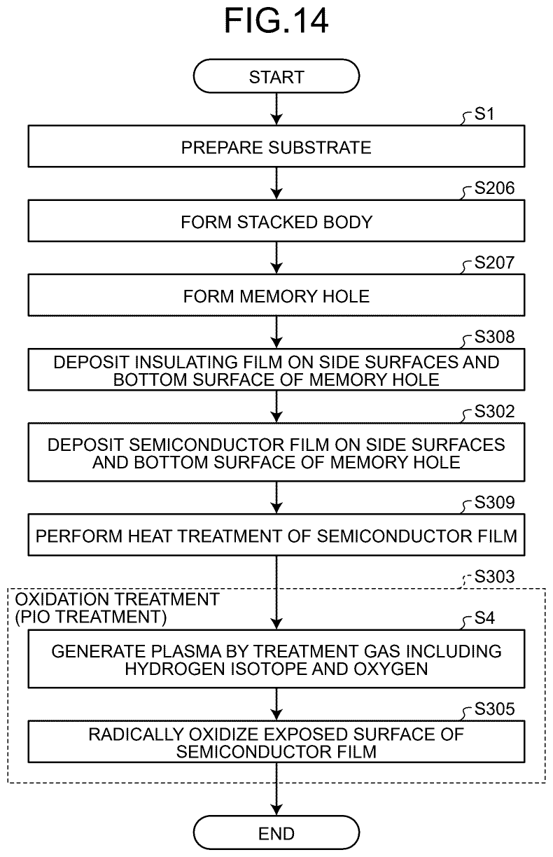

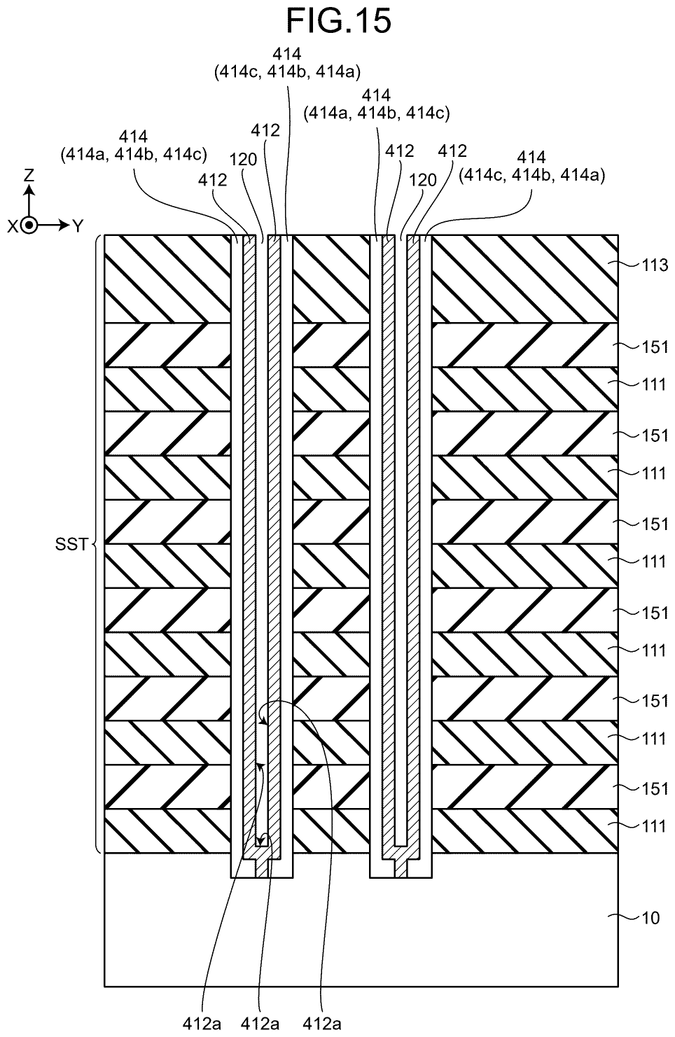

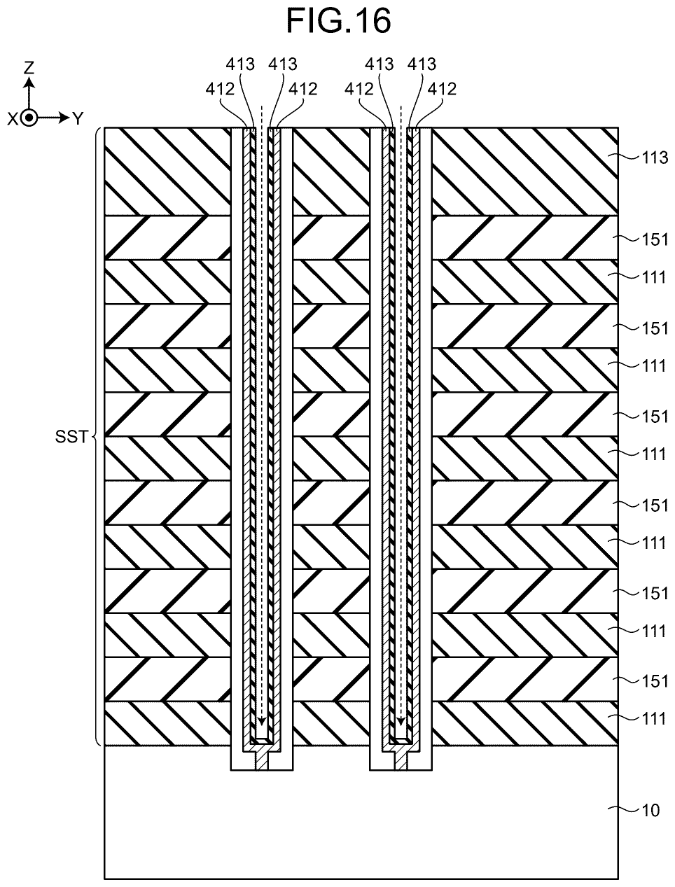

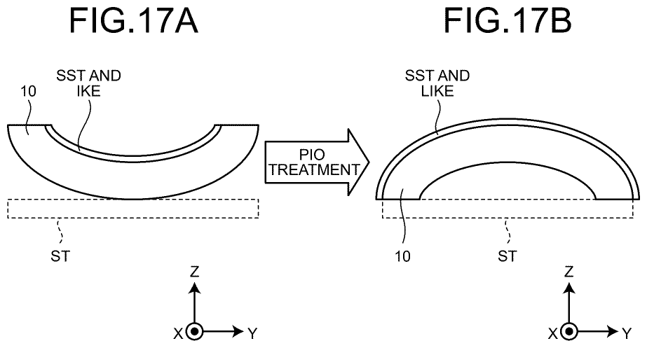

Alternatively, as a third modification of the embodiment, the idea of the embodiment may be applied to exposed surface oxidation of a semiconductor film in a method of manufacturing a semiconductor device 400 such as a three-dimensional memory. For example, the method of manufacturing the semiconductor device 400 may be performed as illustrated in FIGS. 14 to 16. FIG. 14 is a flowchart illustrating the method of manufacturing the semiconductor device 400 according to the third modification of the embodiment. FIGS. 15 and 16 are YZ cross-sectional diagrams illustrating the method of manufacturing the semiconductor device 400. FIGS. 17A and 17B are YZ cross-sectional diagrams illustrating warpage of the substrate 10.

After S1 to S207 are performed in the same manner as in the second modification of the embodiment, as illustrated in FIG. 15, an insulating film 414 is deposited on the side surfaces and the bottom surface of the memory hole 120 by the CVD method or the like (S308). The insulating film 414 may be deposited as a multilayer film including a block insulating film 414a, a charge accumulation film 414b, and a tunnel insulating film 414c.

The block insulating film 414a, the charge accumulation film 414b, and the tunnel insulating film 414c are sequentially deposited on the side surfaces and the bottom surface of the memory hole 120. The block insulating film 414a may be formed of an insulator such as silicon oxide. The charge accumulation film 414b can be formed of an insulator such as silicon nitride. The tunnel insulating film 414c may be formed of an insulator such as silicon oxide. The block insulating film 414a, the charge accumulation film 414b, and the tunnel insulating film 414c at a portion of the bottom surface of the memory hole are selectively removed.

A semiconductor film 412 is deposited on the side surfaces and the bottom surface of the memory hole (S302). The semiconductor film 412 may be formed of a material containing a semiconductor substantially free of impurities (for example, polysilicon) as a main component.

The semiconductor film 412 is subjected to heat treatment at a predetermined temperature (S309), and the crystallinity of the semiconductor film 412 is improved.

At this time, the substrate 10 tends to warp convexly toward the −Z side as a whole as illustrated in FIG. 17A due to the difference in a direction and a deformation amount of thermal deformation of each film formed on the +Z side of the substrate 10. The substrate 10 warped convexly toward the −Z side is difficult to handle because it is difficult to vacuum-adsorb to a stage ST of the apparatus in the later process.

On the other hand, the substrate 10 is carried into the substrate treatment apparatus 1 (see FIG. 3), and the semiconductor film 412 is subjected to oxidation treatment (S303).

The oxidation treatment (S303) may be performed by PIO treatment in which the semiconductor film 412 is radically oxidized by using a plasma generated by a treatment gas including a hydrogen isotope gas and an oxygen gas in the substrate treatment apparatus 1.

In the substrate treatment apparatus 1, the controller 8 applies a radio-frequency voltage between the electrode 3b and the electrode 5, and generates a plasma PL in the treatment chamber CH by a treatment gas including a hydrogen isotope gas (for example, D₂ gas) and an oxygen gas (O₂ gas) (S4). By applying a radio-frequency voltage between the electrode 3b and the electrode 5, an induction magnetic field is formed in the treatment chamber CH. The hydrogen isotope gas (for example, D₂ gas) and the oxygen gas (O₂ gas) included in the treatment gas are plasma-excited respectively, and for example, a donut-shaped plasma PL is formed. The plasma PL may be a plasma having a low electrical potential. The D₂ gas and the O₂ gas are dissociated by the plasma PL respectively, and reactive species such as oxidation radicals such as hydroxy radical OH⁺, deuterium ions, and oxygen ions are generated. Since the electrical potential of the plasma PL is low, deuterium ions and oxygen ions are not accelerated, and oxidation radicals and the like in the treatment gas are substantially uniformly supplied to the vicinity of an exposed surface 412a of the semiconductor film 412 through the memory hole 120.

As a result, the semiconductor film 412 is radically oxidized (S305). As illustrated in FIG. 16, the radical oxidation may be performed in the vicinity of an exposed surface 412a (see FIG. 15) in the semiconductor film 412, and a portion in the vicinity of the exposed surface 412a in the semiconductor film 412 may be replaced with an oxide film 413. Dotted arrows in FIG. 16 indicate that oxidation radicals and ions in the treatment gas are substantially uniformly supplied to the vicinity of the exposed surface 412a of the semiconductor film 412.

At this time, since the direction and the deformation amount of the thermal deformation of the oxide film 413 are added in addition to the difference in the direction and the deformation amount of the thermal deformation of each film formed on the +Z side of the substrate 10, the substrate 10 may be warped convexly to the +Z side as a whole as illustrated in FIG. 17B. The substrate 10 warped convexly toward the +Z side is easy to handle, for example, it is easy to vacuum-adsorb to the stage ST of the apparatus in the later process.

Thereafter, the core member is embedded in the memory hole 120. The core member may be formed of an insulator such as silicon oxide. As a result, columnar bodies penetrating the stacked body SST in the Z direction are formed.

The sacrificial layers 151 of the stacked body SST are removed. Insulating films are formed on the exposed surfaces of voids formed by the removal. The insulating film may be formed of an insulator such as aluminum oxide. Conductive layers 112 are further embedded in the voids. The conductive layer 112 may be formed of a material containing a conductive material (for example, a metal such as tungsten) as a main component. As a result, a stacked body SSTa in which the conductive layers 112 and the insulating layers 111 are alternately and repeatedly stacked is formed.

As a result, the memory cell array structure MCA (see FIG. 13) in which the multiple memory cells MC are three-dimensionally arranged is formed. In the memory cell array structure MCA, the multiple memory cells MC are formed at multiple positions where the multiple conductive layers 112 and semiconductor films SF of multiple columnar bodies PL intersect in the stacked body SSTa. Note that a conductive region (not illustrated) disposed on the +Z side of the stacked body SSTa functions as a source region in the memory cell array structure MCA. The conductive layer 112 closest to the +Z side among the multiple conductive layers 112 functions as a source-side select gate line. The conductive layer 112 closest to the −Z side among the multiple conductive layers 112 functions as a drain-side select gate line. The remaining conductive layers 112 among the multiple conductive layers 112 each function as a word line.

That is, the semiconductor device 400 functioning as a three-dimensional memory is manufactured.

In this way, in the method of manufacturing the semiconductor device 400, the exposed surface 412a of the semiconductor film 412 is radically oxidized by using a plasma generated by a treatment gas including a hydrogen isotope gas and an oxygen gas. As a result, radical oxidation can be efficiently performed as compared with a case where the exposed surface 412a of the semiconductor film 412 is radically oxidized by using a plasma generated by a treatment gas including a hydrogen gas and an oxygen gas.

Furthermore, in the method of manufacturing the semiconductor device 400, the exposed surface 412a of the semiconductor film 412 is efficiently radically oxidized, so that the direction of warpage of the substrate 10 can be easily changed from the direction convex to the −Z side to the direction convex to the +Z side.

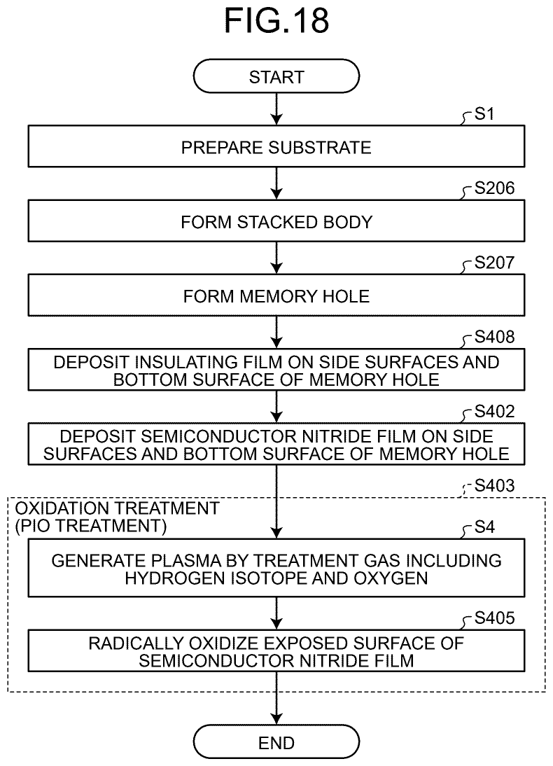

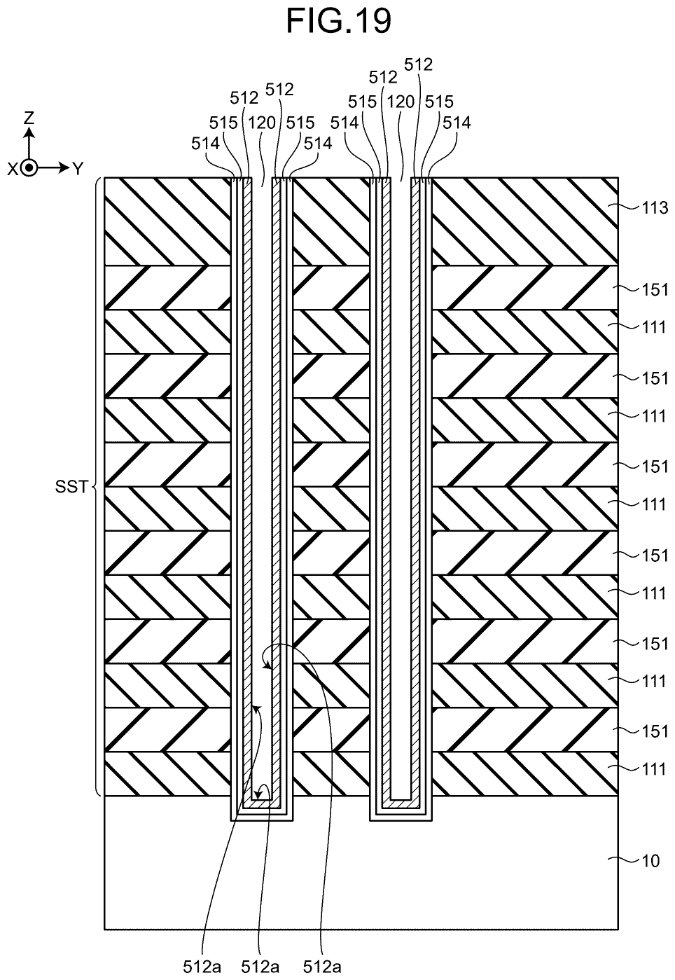

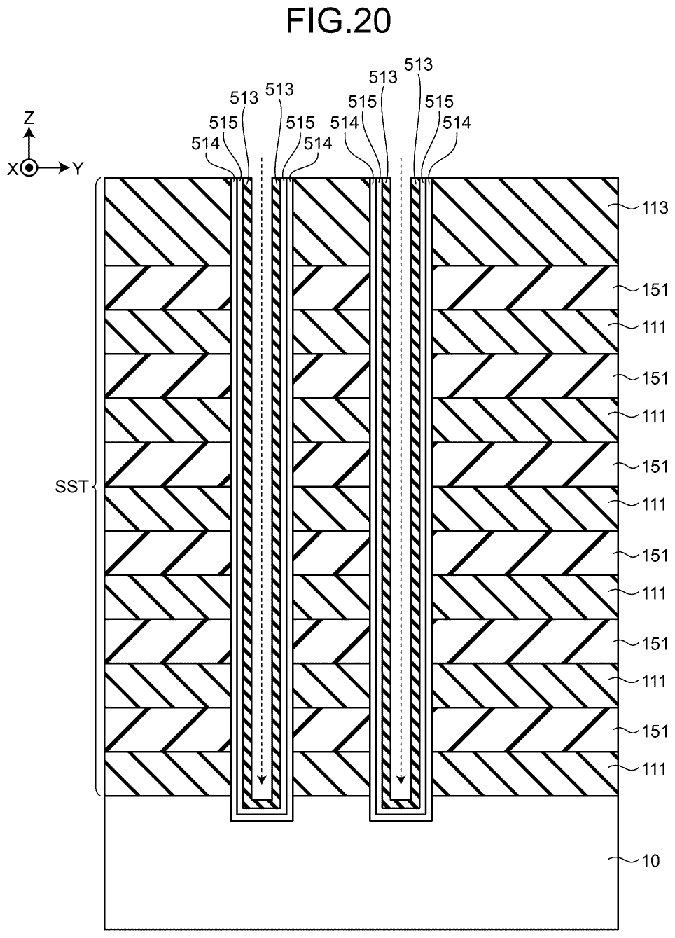

Alternatively, as a fourth modification of the embodiment, the idea of the embodiment may be applied to formation of a tunnel insulating film in a method of manufacturing a semiconductor device 500 such as a three-dimensional memory. For example, the method of manufacturing the semiconductor device 500 may be performed as illustrated in FIGS. 18 to 20. FIG. 18 is a flowchart illustrating the method of manufacturing the semiconductor device 500 according to the fourth modification of the embodiment. FIGS. 19 and 20 are YZ cross-sectional diagrams illustrating the method of manufacturing the semiconductor device 300.

After S1 to S207 are performed in the same manner as in the second modification of the embodiment, as illustrated in FIG. 19, an insulating film is deposited on the side surfaces and the bottom surface of the memory hole 120 by the CVD method or the like (S408).

On the side surfaces and the bottom surface of the memory hole 120, a block insulating film 514 and a charge accumulation film 515 are sequentially deposited as insulating films. The block insulating film 514 may be formed of an insulator such as silicon oxide. The charge accumulation film 515 may be formed of an insulator such as silicon nitride.

Further, as illustrated in FIG. 19, a semiconductor nitride film 512 is deposited on the side surfaces and the bottom surface of the memory hole 120 by a CVD method or the like (S402). The semiconductor nitride film 512 can be formed of a material containing silicon nitride as a main component.

When the semiconductor nitride film 512 is deposited, the substrate 10 is carried into the substrate treatment apparatus 1 (see FIG. 3), and the semiconductor nitride film 512 is subjected to oxidation treatment (S403).

The oxidation treatment (S403) may be performed by PIO treatment in which the semiconductor nitride film 512 is radically oxidized by using a plasma generated by a treatment gas including a hydrogen isotope gas and an oxygen gas in the substrate treatment apparatus 1.

In the substrate treatment apparatus 1, the controller 8 applies a radio-frequency voltage between the electrode 3b and the electrode 5, and generates a plasma PL in the treatment chamber CH by a treatment gas including a hydrogen isotope gas (for example, D₂ gas) and an oxygen gas (O₂ gas) (S4). By applying a radio-frequency voltage between the electrode 3b and the electrode 5, an induction magnetic field is formed in the treatment chamber CH. The hydrogen isotope gas (for example, D₂ gas) and the oxygen gas (O₂ gas) included in the treatment gas are plasma-excited respectively, and for example, a donut-shaped plasma PL is formed. The plasma PL may be a plasma having a low electrical potential. The D₂ gas and the O₂ gas are dissociated by the plasma PL respectively, and reactive species such as oxidation radicals such as hydroxy radical OH⁺, deuterium ions, and oxygen ions are generated. Since the electrical potential of the plasma PL is low, deuterium ions and oxygen ions are not accelerated, and oxidation radicals and the like in the treatment gas are substantially uniformly supplied to the vicinity of an exposed surface 512a of the semiconductor nitride film 512 through the memory hole 120.

As a result, the semiconductor nitride film 512 is radically oxidized (S405). As illustrated in FIG. 20, the radical oxidation may be performed on the entire semiconductor nitride film 512, and the entire semiconductor nitride film 512 may be replaced with an oxide film 513. Dotted arrows in FIG. 20 indicate that oxidation radicals and ions in the treatment gas are substantially uniformly supplied to the vicinity of the exposed surface 512a of the semiconductor nitride film 512. As a result, a tunnel insulating film including the oxide film 513 is formed on the side surfaces and the bottom surface of the memory hole 120.

In the memory hole 120, the block insulating film 514, the charge accumulation film 515, and the tunnel insulating film 513 at a portion of the bottom surface of the memory hole 120 are selectively removed.

A semiconductor film is deposited on the side surfaces and the bottom surface of the memory hole 120. The semiconductor film may be formed of a material containing a semiconductor substantially free of impurities (for example, polysilicon) as a main component. The semiconductor film is subjected to heat treatment at a predetermined temperature, and the crystallinity of the semiconductor film is improved. Then, a core member is embedded in the memory hole 120. The core member may be formed of an insulator such as silicon oxide. As a result, columnar bodies penetrating the stacked body SST in the Z direction are formed.

The sacrificial layers 151 of the stacked body SST are removed. Insulating films are formed on the exposed surfaces of voids formed by the removal. The insulating film may be formed of an insulator such as aluminum oxide. Conductive layers 112 are further embedded in the voids. The conductive layer 112 may be formed of a material containing a conductive material (for example, a metal such as tungsten) as a main component. As a result, a stacked body SSTa in which the conductive layers 112 and the insulating layers 111 are alternately and repeatedly stacked and the insulating layer 113 is further stacked is formed.

As a result, the memory cell array structure MCA (see FIG. 13) in which the multiple memory cells MC are three-dimensionally arranged is formed. In the memory cell array structure MCA, the multiple memory cells MC and select gates SGS and SGD at both ends in the Z direction thereof are formed at multiple positions where the multiple conductive layers 112 and semiconductor films SF of multiple columnar bodies PL intersect in the stacked body SSTa. Note that a conductive region (not illustrated) disposed on the −Z side of the stacked body SSTa functions as a source region in the memory cell array structure MCA. The conductive layer 112 closest to the −Z side among the multiple conductive layers 112 functions as a source-side select gate line. The conductive layer 112 closest to the +Z side among the multiple conductive layers 112 functions as a drain-side select gate line. The remaining conductive layers 112 among the multiple conductive layers 112 each function as a word line.

That is, the semiconductor device 500 functioning as a three-dimensional memory is manufactured.

In this way, in the method of manufacturing the semiconductor device 500, the semiconductor nitride film 512 is radically oxidized by using a plasma generated by a treatment gas including a hydrogen isotope gas and an oxygen gas. As a result, radical oxidation can be efficiently performed as compared with a case where the semiconductor nitride film 512 is radically oxidized by using a plasma generated by a treatment gas including a hydrogen gas and an oxygen gas.

In addition, in the method of manufacturing the semiconductor device 500, the step coverage of the oxide film 513 can be easily improved by using the radical oxidation with the treatment gas including the hydrogen isotope gas for the formation of the tunnel insulating film, and the structure in which an interface between the charge accumulation film and the tunnel insulating film is terminated with the hydrogen isotope (for example, deuterium) can be formed. As a result, it is possible to suppress the occurrence of a coupling defect due to an electrical stress at the interface between the charge accumulation film and the tunnel insulating film during a write operation and an erase operation of data to the memory cells MC, and it is possible to suppress a malfunction due to the coupling defect. Therefore, in the semiconductor device 500, the operation reliability of the memory cells MC can be improved.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device, the method comprising:
radically oxidizing a first film by using a plasma generated by a treatment gas including a hydrogen isotope gas.

2. The method of manufacturing a semiconductor device according to claim 1, wherein
the radically oxidizing includes
radically oxidizing the first film by using a plasma generated by the treatment gas including the hydrogen isotope gas and an oxygen gas.

3. The method of manufacturing a semiconductor device according to claim 1, wherein
the radically oxidizing includes
radically oxidizing the first film by using a plasma generated by the treatment gas including a hydrogen gas, the hydrogen isotope gas, and an oxygen gas.

4. The method of manufacturing a semiconductor device according to claim 1, wherein
the radically oxidizing includes
radically oxidizing the first film by using a plasma generated by the treatment gas including the hydrogen isotope gas and an oxygen isotope gas.

5. The method of manufacturing a semiconductor device according to claim 1, wherein
the radically oxidizing includes
radically oxidizing the first film by using a plasma generated by the treatment gas including the hydrogen isotope gas, an oxygen gas, and a rare gas.

6. The method of manufacturing a semiconductor device according to claim 1, wherein
the radically oxidizing includes
radically oxidizing the first film by using a plasma generated by the treatment gas including a hydrogen gas, the hydrogen isotope gas, an oxygen gas, and a rare gas.

7. The method of manufacturing a semiconductor device according to claim 1, wherein
the radically oxidizing includes
radically oxidizing the first film by using a plasma generated by the treatment gas including the hydrogen isotope gas, an oxygen isotope gas, and a rare gas.

8. The method of manufacturing a semiconductor device according to claim 1, wherein
the radically oxidizing includes
radically oxidizing the first film at a temperature of 300° C. or more and 800° C. or less by using a plasma generated by the treatment gas including the hydrogen isotope gas.

9. The method of manufacturing a semiconductor device according to claim 1, wherein
the radically oxidizing includes
radically oxidizing the first film at a pressure of 50 Pa or more and 300 Pa or less by using a plasma generated by the treatment gas including the hydrogen isotope gas.

10. The method of manufacturing a semiconductor device according to claim 1, wherein
the radically oxidizing includes
radically oxidizing the first film by using a plasma generated by the treatment gas including the hydrogen isotope gas at a flow rate ratio of 5% or more and 95% or less.

11. The method of manufacturing a semiconductor device according to claim 1, wherein
the radically oxidizing includes
radically oxidizing a vicinity of an exposed surface of the first film by using a plasma generated by the treatment gas including the hydrogen isotope gas.

12. The method of manufacturing a semiconductor device according to claim 1, wherein
the radically oxidizing includes
radically oxidizing an entire first film by using a plasma generated by the treatment gas including the hydrogen isotope gas.

13. The method of manufacturing a semiconductor device according to claim 1, further comprising:
forming a stacked body in which first insulating films and second insulating films are alternately stacked multiple times;
forming a hole extending in a stacking direction through the stacked body; and
depositing a semiconductor nitride film as the first film on inner side surfaces and a bottom surface of the hole, wherein
the radically oxidizing includes
generating a plasma of the treatment gas to radically oxidize an exposed surface of the semiconductor nitride film.

14. The method of manufacturing a semiconductor device according to claim 1, further comprising:
forming a stacked body in which first insulating films and second insulating films are alternately stacked multiple times;
forming a hole extending in a stacking direction through the stacked body;
depositing a third insulating film on inner side surfaces and a bottom surface of the hole; and
depositing a semiconductor film as the first film on inner side surfaces and a bottom surface of the third insulating film in the hole, wherein
the radically oxidizing includes
generating a plasma of the treatment gas to radically oxidize an exposed surface of the semiconductor film.

15. The method of manufacturing a semiconductor device according to claim 1, further comprising:
forming a stacked body in which first insulating films and second insulating films are alternately stacked multiple times;
forming a hole extending in a stacking direction through the stacked body;
depositing a third insulating film on inner side surfaces and a bottom surface of the hole; and
depositing a semiconductor nitride film as the first film on inner side surfaces and a bottom surface of the third insulating film in the hole, wherein
the radically oxidizing includes
generating a plasma of the treatment gas to radically oxidize an exposed surface of the semiconductor nitride film.

16. The method of manufacturing a semiconductor device according to claim 1, wherein
the radically oxidizing includes
radically oxidizing the first film by uniformly supplying a plasma generated by a treatment gas including the hydrogen isotope gas to a surface of the first film.

17. A substrate treatment apparatus comprising:
a stage disposed in a treatment chamber, on which a substrate is placed, and including a first electrode;
a gas supply system capable of supplying a treatment gas including a hydrogen isotope gas toward the stage in the treatment chamber;
a second electrode disposed at a position separated from the stage outside the treatment chamber; and
an exhaust system capable of adjusting a pressure in the treatment chamber, wherein
a plasma is capable of being generated in the treatment chamber by applying a radio-frequency voltage between the first electrode and the second electrode.

18. The substrate treatment apparatus according to claim 17, wherein
the gas supply system is capable of supplying the treatment gas including the hydrogen isotope gas and an oxygen isotope gas toward the stage in the treatment chamber.

19. The substrate treatment apparatus according to claim 17, wherein
the gas supply system is capable of supplying the treatment gas including the hydrogen isotope gas, an oxygen gas, and a rare gas toward the stage in the treatment chamber.

20. The substrate treatment apparatus according to claim 17, wherein
the gas supply system is capable of supplying the treatment gas including the hydrogen isotope gas, an oxygen isotope gas, and a rare gas toward the stage in the treatment chamber.
